(19) United States
(12) Patent Application Publication
(10) Pub. No.: US 2010/0312744 A1
(43) Pub. Date: Dec. 9, 2010

(54) SYSTEM FOR BATTERY PROGNOSTICS

(75) Inventors: Danil V. Prokhorov, Canton, MI (US); Setu Madhavi Namburu, Boston, MA (US); Liu Qiao, Ann Arbor, MI (US)

Correspondence Address: GIFFORD, KRASS, SPRINKLE,;ANDERSON & CITKOWSKI, P.C., P.O. BOX 7021, TROY, MI, 48007-7021, US

(73) Assignee: Toyota Motor Engineering & Manufacturing North America, Inc., Erlanger, KY (US)

(21) Appl. No.: 12/480,975

(22) Filed: Jun. 9, 2009

(51) Int. Cl. G06N 7/02; G01R 31/36; G06F 19/00; G06F 15/18; G06N 3/02

(52) U.S. Cl. 706/52; 702/63; 706/12; 706/15

(57) ABSTRACT

A battery prognosis system for estimating the remaining useful life of a battery includes a sensor input, a conversion module, and a mapping module. The sensor input is capable of receiving a measurement signal from a sensor measuring properties of the battery. The conversion module is in electronic communication with the sensor input to receive the measurement signal and processes the measurement signal into an output signal of internal parameters of the battery. A mapping model trained on actual battery performance data in the mapping module maps the output signal and time variant parameters related to the output signal to generate a battery life signal corresponding to an estimate of the remaining useful life of the battery.

### FIELD OF THE INVENTION

The present invention relates to a system and method for battery prognostics. More particularly, the invention relates to a system and method for estimating the remaining useful life of a battery using a model trained on actual battery performance data.

### BACKGROUND OF THE INVENTION

There are many previously known model-based systems and methods for estimating the remaining useful life of a battery. Such systems and methods typically utilize analytical models of battery electrochemistry and other theoretical knowledge of other battery properties. However, in order to function these analytical models require time consuming and costly calibrations which are specific to each individual battery type. A further disadvantage of these known analytical models results from the range of variations in the complex electrochemistry of a battery. Batteries of the same type vary considerably in their electrochemical parameters; however it is also known that a single battery's electrochemical parameters undergo considerable variations during the lifetime of the battery. These variations in electrochemical parameters are extremely difficult to account for in purely analytical models and therefore result in inaccurate estimates of the remaining useful life of a battery.

Accordingly, it is desirable to have a system and method which is capable of accurately estimating the remaining useful life of a battery. Further it is desirable that such a system and method does not require time consuming and costly calibration on an individual battery type in order to function.

### SUMMARY OF THE INVENTION

According to one aspect of the invention, a system and method for estimating the remaining useful life of a battery using a model trained on actual battery performance data is provided. The battery prognosis system includes a sensor input, a conversion module in electronic communication with the sensor input, and a mapping module which is in electronic communication with the conversion module. The sensor input is capable of receiving a measurement signal from a sensor measuring battery properties. The conversion module receives the measurement signal from the sensor input and processes the measurement signal into an output signal corresponding to internal parameters of the battery. The mapping module receives the output signal from the conversion module, and uses a mapping model trained on actual battery performance data to generate a battery life signal based upon the output signal and time variant parameters related to the output signal. The battery life signal corresponds to an estimate of the remaining useful life (RUL) of the battery.

According to another aspect of the invention the sensor input is in electronic communication with a temperature sensor and/or an electrical impedance sensor to receive a measurement signal related to battery temperature and/or the electrical impedance of the battery. The conversion module processes the temperature and electrical impedance properties into the output signal which includes the internal parameters of the resistance, capacitance and voltage. The output signal is received by the mapping module which uses the mapping model to determine a plurality of intermediate quantities which include an available capacity of the battery and a gauge of the condition of the battery. The mapping model then generates a battery life signal based upon the intermediate quantities, the output signal and the time variant parameters of the output signal. The time variant parameters of the output signal relate to the change of the output signal over the life of the battery, such that the temporal relationship between the output signals over the life of the battery is taken into account when determining the battery life signal.

### BRIEF DESCRIPTION OF THE DRAWINGS

A better understanding of the present invention will be had upon reference to the following detailed description when read in conjunction with the accompanying drawings wherein like reference characters refer to like parts throughout the several views and in which:

FIG. 1 is a block diagram of a battery prognosis system for estimating the remaining useful life of a battery;

FIG. 2 is a chart depicting the battery life signal versus time; and

FIG. 3 is a flowchart illustrating the method for estimating the remaining useful life of a battery.

### DETAILED DESCRIPTION OF THE INVENTION

The present invention has utility as a battery prognosis system and method for estimating the remaining useful life of a battery. By using a model which has been trained on actual battery performance data rather than purely analytical models of battery electrochemistry, the inventive battery prognosis system is capable of providing accurate estimates of the remaining useful life of a battery. Further, as the model used in the inventive battery prognosis system does not require costly and time consuming calibrations on a specific battery type prior to use, the inventive battery prognosis system can be used on a variety of different battery types without additional calibrations or training.

The system and method are configured to be used in conjunction with any type of vehicle having a battery. The vehicle may have an internal combustion engine, a hybrid power plant including an internal combustion engine as well as an electric motor, or any other type of propulsion system which utilizes a battery. Further, the system and method may be used in any other application in which it is desirable to have an estimate of the remaining useful life of a battery, illustratively including power systems, communication systems, computer systems and equipment which is fully or partially powered by batteries, such as portable telephones or radios.

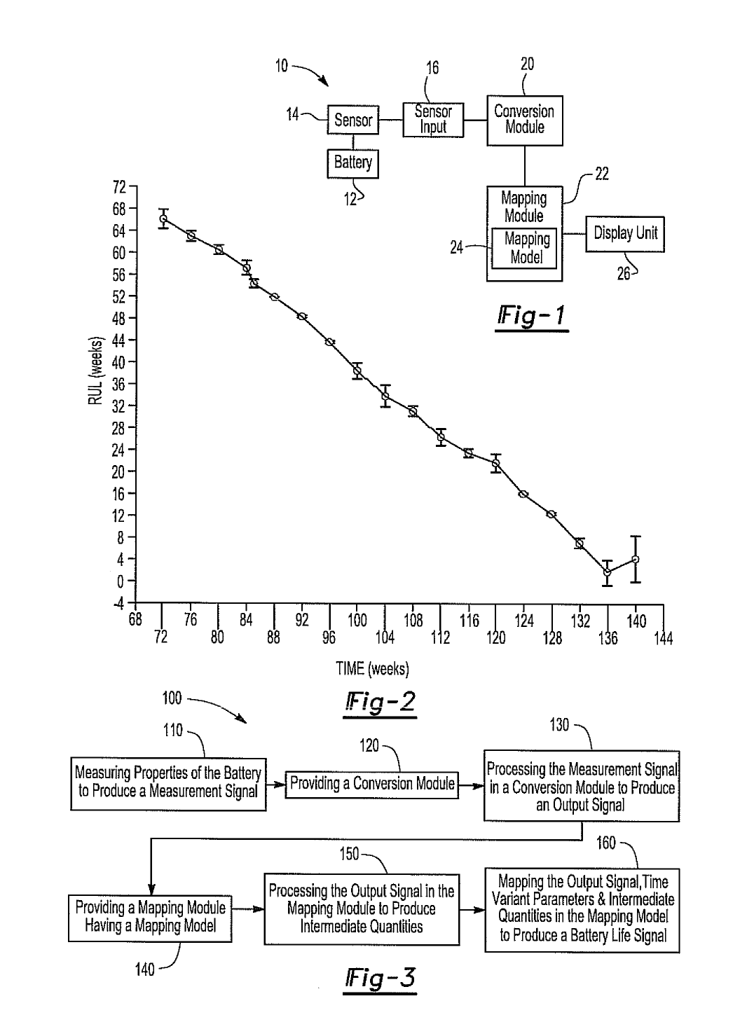

With reference to FIG. 1, an inventive battery prognostics system for estimating the remaining useful life of a battery is illustrated generally at 10. A battery 12 is connected to a sensor 14 which measures battery properties to produce a measurement signal. The sensor 14 may be any of the following types of sensors illustratively including a temperature sensor, a volt meter, a current sensor, and an electrical impedance sensor or any combination thereof. The sensor 14 converts the measured battery property into a measurement signal corresponding to the measured battery property.

Preferably, the sensor 14 includes a temperature sensor and an electrical impedance sensor. The temperature sensor measures battery properties relating to battery temperature, illustratively including ambient temperature, battery surface temperature, terminal temperature, and internal battery temperature. The electrical impedance sensor measures battery properties related to the electrical impedance of the battery. The electrical impedance sensor excites the battery by providing a small electronic excitation current at a single or a plurality of frequencies, and receives in response a signal current from the battery.

The measurement signal provided by the sensor 14 is received by a sensor input 16. The sensor 14 may be connected directly to the sensor input 16. In the alternative, the sensor input 16 receives the measurement signal produced by the sensor 14 after it has been received and/or processed by another system. As such, the sensor input 16 receives the measurement signal produced by the sensor 14 either directly or indirectly.

The system 10 processes the measurement signals received by the sensor input 16 into an estimate of the remaining useful life of the battery through the use of two electronically controlled modules. It will be appreciated that the two electronically controlled modules and their respective models may be implemented by a processor, such as a microprocessor, under the control of programmed software.

The first electronically controlled module constitutes a conversion module 20 in electronic communication with the sensor input 16 so as to receive the measurement signal.

The measurement signal is processed by the conversion module 20 into an output signal of internal parameters of the battery. The conversion model 20 utilizes any known physical formulas capable of converting an input of a measurement signal relating to battery properties into an output of internal parameters of a battery. The internal parameters of the battery illustratively include voltage, current, resistance, and capacitance of the battery or any combination thereof. Preferably the conversion module 20 processes a measurement signal relating to the temperature of the battery and the electrical impedance of the battery, into an output signal of the resistance and capacitance of the battery.

The measurement signals received by the conversion module 20 may be continuously processed. In the alternative, the conversion module 20 may only process the measurement signals at regular intervals of time defined by the specific application. For example, the measurement signal from a battery in an internal combustion engine is only processed once an hour, whereas the measurement signal from a battery in a hybrid or electronic engine is processed several times in an hour.

The output signal is then outputted from the conversion module 20 to the second electronically controlled module, specifically a mapping module 22. The mapping module 22 includes a mapping model 24 trained on actual battery performance data, which will be described in greater detail below. The mapping model 24 first generates a plurality of intermediate quantities from the output signal of internal parameters of the battery.

The intermediate quantities include the available capacity of the battery (state of charge) and a gauge of the condition of the battery (state of health). The State of Charge of a battery is typically defined as the ratio of the available capacity and the rated capacity of the battery. The State of Health is an arbitrary gauge of the condition of a battery compared to the rated condition. The intermediate quantities of State of Charge and State of Health are particularly useful when estimating the remaining useful life of a rechargeable, or secondary batteries, as battery capacity and battery conditions are known to deteriorate over the lifespan of the battery.

The mapping module 24 then generates a battery life signal corresponding to an estimate of the remaining useful life of the battery. The battery life signal is based upon the output signal of internal parameters of the battery, time variant parameters relating to the change of the output signal over time, and the determined intermediate quantities.

The time variant parameters are a collection of the prior output signals of the conversion module 20. The specific number of prior output signals used as the time parameters conforms to how often the measurement signal is processed by the conversion module 20. If the conversion module 20 processes the measurement signal at a regular interval of time, the number of prior output signals used as the time variant parameters is sufficient to generate a representation of the battery's prior utilization. Specifically, if the time interval is a period of one hour, time variant parameters which include the prior 10-20 output signals would be sufficient. However, if the time interval is several times an hour, the number of prior output signals needed in the time variant parameters to generate a sufficient representation of the battery's prior utilization is increased accordingly.

By taking into account the temporal relationship between the various output signals, the mapping model 24 factors the evolution of the battery into the battery life signal. This is important as the mapping model 24 factors the utilization of the battery into the estimate of the remaining useful life. For example, if the battery has been under a high load basing an estimate of the remaining useful life of the battery solely from the output signal will not accurately represent the remaining useful life of the battery under its current history of utilization. However, by using the output signal and the time variant parameters, the estimate of the remaining useful life of the battery will represent the battery's prior utilization. This results in an increase in accuracy of the estimate of the remaining useful life of the battery.

A display unit 26 is in electronic communication with the mapping module 22 to receive the battery life signal. The display unit 26 displays the battery life signal optionally as a chart depicting the remaining useful life of the battery versus time as illustrated in FIG. 2. The vertical brackets about the data points illustrate the estimated range of the remaining useful life of the battery. It will be appreciated, of course, that the display unit 26 is capable of displaying the battery life signal in a multitude of different manners such as a percentage of battery life, a countdown of time until battery depletion or a countdown in time until the battery will have to be replaced or recharged.

The operation and training of the mapping model 24 will now be described. The mapping model 24 constitutes any artificial intelligence systems known in the art capable of producing models from data to realize nonlinear transformations, illustratively including neural networks, fuzzy logic algorithms and any other type of machine learning algorithms.

Prior to use in application, the mapping model 24 is pre-trained on actual battery performance data. The actual battery performance data is supplied by a number of sample batteries. The sample batteries are selected from a varied field of battery types so that the mapping model becomes a generalized battery prognostics system. By using a large and varied field of sample batteries in the training of the mapping model 24, the system 10 is capable of estimating the remaining useful life of even an unknown battery, which is a battery of the type the mapping model 24 was not trained on.

The mapping model 24 receives inputs of internal parameters of the sample batteries, preferably resistance and capacitance, either directly measured from the sample batteries, or outputted by the conversion module 20 from processed measurement signals, preferably temperature and electrical impedance. In addition, the mapping model receives inputs of the intermediate quantities relating to each input of internal parameters. The mapping model 24 amasses a collection of actual battery performance data over repeated charges and discharges of the sample batteries under various loads. The mapping model 24 receives a time note regarding when each input was received. The time note illustratively includes the actual time the input was received, the elapsed time from the start of battery operation, or if the mapping model 24 receives the inputs at regular time intervals the sequential order of the inputs. Upon exhaustion of the remaining useful life of the sample batteries, the mapping model 24 correlates each of the time notes of each of the inputs with the actual remaining useful life of the sample batteries from when each input was received to the depletion of the sample batteries.

As the mapping model 24 is trained on actual battery performance data over repeated charges and discharges of the sample batteries, the temporal relationship between the actual battery performance data and its effect on the remaining useful life of the battery are consequently learned. The temporal relationship is represented in the system 10 as the mapping model 24 bases the estimate of the remaining useful life on a mapping of the output signals and time variant parameters which represent the temporal linkage between the instant output signal and the prior output signals. It will be appreciated that the term “mapping” relates to the model generated function which maps inputs into desired outputs.

In an alternative embodiment, the mapping module 22 is in electronic communication with a training database and a historical database. The training database includes the actual battery performance data used to train the mapping model 24. The actual battery performance data stored in the training database includes the inputs of internal battery parameters, the time notes correlating to the inputs, the intermediate quantities associated with each of the inputs, and the actual remaining useful life of the battery from when the input of internal battery parameters was received to the depletion of the battery. The historical database stores the time variant parameters of the output signals, including the prior output signals and their corresponding intermediate quantities and battery life signals. The mapping model 24 uses the actual battery performance data stored in the training database when mapping the output signal and time variant parameters to generate the battery life signal.

In order to facilitate an understanding of the principles associated with the disclosed system, its method of operation, generally illustrated at 100 in FIG. 3, will now be briefly described. The system 10 first measures property of the battery to produce a measurement signal 110 through the use of a sensor 14. A conversion module 20 is then provided 120. Next, the measurement signal is processed in the conversion module to produce an output signal 130.

A mapping module 22 having a mapping model 24 trained on actual performance data is provided in step 140. The method proceeds to step 150 wherein the output signal of the conversion module 20 is processed in the mapping module 22 to produce intermediate quantities. Finally, in step 160 the mapping model maps the output signal, time variant parameters and the intermediate quantities to produce a battery life signal which corresponds to the remaining useful life of the battery.

From the foregoing, it can be seen that the present invention provides a unique system and method for estimating the remaining useful life of a battery through the use of models trained on actual battery performance data. Having described the inventive system and method, however, many modifications thereto will become apparent to those skilled in the art to which it pertains without deviation from the spirit of the invention as defined by the scope of the appended claims.

It is claimed:

1. A battery prognostics system for estimating the remaining useful life of a battery, said battery prognostics system comprising:
a sensor input capable of receiving at least one measurement signal from at least one sensor which measures at least one property of the battery;
a conversion module in electronic communication with said sensor input to receive said at least one measurement signal, said conversion module processes said at least one measurement signal into an output signal of internal parameters of the battery; and
a mapping module in electronic communication with said conversion module to receive said output signal, said mapping module uses a mapping model having been trained on actual battery performance data to map said output signal and time variant parameters related to said output signal to generate a battery life signal corresponding to an estimate of the remaining useful life of the battery.

2. The battery prognostics system of claim 1, wherein said time variant parameters relate to the evolution of said output signal.

3. The battery prognostics system of claim 1, wherein said mapping model determines a plurality of intermediate quantities based on said output signal, and wherein said mapping model generates said battery life signal based on said output signal and said plurality of intermediate quantities.

4. The battery prognostics system of claim 1, wherein said sensor input is connected to a temperature sensor to receive a measurement signal related to the temperature of the battery.

5. The battery prognostics system of claim 1, wherein said sensor input is connected to an electrical impedance sensor to receive a measurement signal related to the electrical impedance induced by electrical excitation of the battery.

6. The battery prognostics system of claim 1, wherein said output signal includes the internal parameters of resistance of the battery and capacitance of the battery.

7. The battery prognostics system of claim 3 wherein said plurality of intermediate quantities include an available capacity of the battery.

8. The battery prognostics system of claim 3, wherein said plurality of intermediate quantities include a gauge of the condition of the battery.

9. The battery prognostics system of claim 1, wherein said mapping model is selected from the group consisting of neural networks, machine learning algorithms, and fuzzy logic systems.

10. A method for estimating the remaining useful life of a battery, said method comprising the steps of:
measuring at least one property of the battery so as to produce a measurement signal;
providing a conversion module;
processing said measurement signal in said conversion module so as to generate an output signal of internal parameters of the battery;
providing a mapping module having a mapping model, said mapping model having been trained on actual battery performance data;
processing said output signal and time variant parameters related to said output signal in said mapping module so as to generate a battery life signal corresponding to an estimate of the remaining useful life of the battery.

11. The method of claim 10, wherein said time variant parameters relate to the evolution of said output signal.

12. The method of claim 10, wherein said mapping model determines a plurality of intermediate quantities based on said output signal and processes said plurality of intermediate quantities along with said output signal to generate said battery life signal.

13. The method of claim 10, wherein said measurement signal includes measured properties related to the temperature of the battery.

14. The method of claim 10, wherein said measurement signal includes measured properties related to the electrical impedance induced by electrical excitation of the battery.

15. The method of claim 10, wherein said output signal includes said internal parameters of resistance of the battery and capacitance of the battery.

16. The method of claim 12, wherein said plurality of intermediate quantities include an available capacity of the battery.

17. The method of claim 12, wherein said plurality of intermediate quantities include a gauge of the condition of the battery.

18. The method of claim 1, wherein said mapping model is selected from the group consisting of neural networks, machine learning algorithms, and fuzzy logic systems.
